(19) United States
(12) Patent Application Publication
(10) Pub. No.: US 2024/0274625 A1
(43) Pub. Date: Aug. 15, 2024

(54) METHOD AND APPARATUS FOR MANUFACTURING DISPLAY DEVICE

(71) Applicant: Samsung Display Co., LTD., Yongin-si (KR)

(72) Inventors: Yungbin CHUNG, Yongin-si (KR); Changhee LEE, Yongin-si (KR); Yijoon AHN, Yongin-si (KR); Sungjoo KWON, Yongin-si (KR); Joonyong PARK, Yongin-si (KR); Hyuneok SHIN, Yongin-si (KR); Juhyun LEE, Yongin-si (KR); Samtae JEONG, Yongin-si (KR)

(21) Appl. No.: 18/432,861

(22) Filed: Feb. 5, 2024

(30) Foreign Application Priority Data
Feb. 15, 2023 (KR) 10-2023-0020114

(51) Int. Cl. H01L 27/12; C23C 16/27; C23C 16/44; C23C 16/455; H10K 59/12; H10K 59/121

(52) U.S. Cl. CPC H01L 27/127; C23C 16/27; C23C 16/4408; C23C 16/45565; C23C 16/45574; H01L 27/1222; H01L 27/1225; H01L 27/1255; H10K 59/1201; H10K 59/1213

(57) ABSTRACT

An apparatus for manufacturing a display device includes a stage on which a display substrate is arranged, a nozzle portion facing the stage, where the nozzle portion supplies gas to the display substrate to form at least one selected from a base portion and a graphene layer on the display substrate, and a driver connected to at least one of the nozzle portion and the stage, where the driver linearly moves at least one selected from the nozzle portion and the stage in a predetermined direction. The nozzle portion forms the at least one selected from the base portion and the graphene layer on the display substrate based on a relative motion thereof with the stage.

This application claims priority to Korean Patent Application No. 10-2023-0020114, filed on Feb. 15, 2023, and all the benefits accruing therefrom under 35 U.S.C. § 119, the content of which in its entirety is herein incorporated by reference.

### BACKGROUND

### 1. Field

One or more embodiments relate to a method and apparatus, and more particularly, to a method and apparatus for manufacturing a display device.

### 2. Description of the Related Art

Mobile electronic devices are widely used in various fields. In addition to small electronic devices, such as mobile phones, tablet personal computers (PCs) have recently been widely used as mobile electronic devices.

Such a mobile electronic device typically includes a display device for providing a user with visual information, such as images or video, to support various functions. Recently, as other parts for driving the display device have become smaller, the proportion occupied by display devices in electronic devices has been gradually increasing, and a structure capable of being bent from a flat state to have a certain angle has also been developed.

Various materials may be used for such a display device, and a display device having high performance may be manufactured by using a graphene layer.

### SUMMARY

A transfer process is typically performed to use a graphene layer in the related art. In this case, when the transfer process is performed to use the graphene layer during the manufacturing of a display device, the process is complex and it may be difficult to form a precise pattern, and accordingly, it may be difficult to manufacture a high-quality display device.

One or more embodiments include a method and apparatus for manufacturing a display device, in which a display device including a graphene layer may be manufactured through a simple process.

Additional aspects will be set forth in part in the description which follows and, in part, will be apparent from the description, or may be learned by practice of the presented embodiments of the disclosure.

According to one or more embodiments, an apparatus for manufacturing a display device includes a stage on which a display substrate is arranged, a nozzle portion facing the stage, where the nozzle portion supplies gas to the display substrate to form at least one of a base portion and a graphene layer on the display substrate, and a driver connected to at least one of the nozzle portion and the stage, where the driver linearly moves at least one of the nozzle portion and the stage in a predetermined direction, where the nozzle portion forms the at least one of the base portion and the graphene layer on the display substrate based on a relative motion thereof with the stage.

In an embodiment, the apparatus may further include a heater which applies heat to the display substrate.

In an embodiment, the apparatus may further include a power supply portion electrically connected to the stage and the nozzle portion.

In an embodiment, the apparatus may further include a light source portion arranged at the nozzle portion or apart from the nozzle portion, where the light source portion may linearly move a predetermined direction and emit light to the display substrate.

In an embodiment, the nozzle portion may include a first nozzle portion which supplies a first raw material to the display substrate, a second nozzle portion which supplies a second raw material to the display substrate, and a third nozzle portion arranged between the first nozzle portion and the second nozzle portion, where the third nozzle portion supplies a purge gas.

In an embodiment, based on a planar shape of the nozzle portion, the second nozzle portion may be further from a center of the planar shape of the nozzle portion than the first nozzle portion is.

In an embodiment, the nozzle portion may further include a suction portion arranged between the first nozzle portion and the third nozzle portion and at an outer edge of the planar shape of the nozzle portion.

In an embodiment, the second nozzle portion may be provided in plural, and a plurality of second nozzle portions may be arranged between the third nozzle portion and the suction portion.

In an embodiment, the suction portion may include a first suction portion arranged between the first nozzle portion and the third nozzle portion, and a second suction portion arranged at the outer edge of the planar shape of the nozzle portion.

In an embodiment, the second suction portion may be provided in plural, and in a plan view, the first nozzle portion, a plurality of second nozzle portions, the third nozzle portion, and the first suction portion may be arranged inside an arbitrary closed loop in which a plurality of second suction portions is arranged.

In an embodiment, the apparatus may further include a position sensor apart from the stage, where the position sensor may sense a position of at least one selected from the display substrate and the nozzle portion.

In an embodiment, the nozzle portion may be provided with a hole having a diameter of 0.5 micrometer (μm) or greater and 100 μm or less.

In an embodiment, the base portion may include at least one selected from polyimide and transition metals.

According to one or more embodiments, a method of manufacturing a display device includes forming a base portion on a display substrate, supplying a second graphene raw material onto the base portion while linearly moving at least one selected from the display substrate and a nozzle portion facing the display substrate, and forming a graphene layer on the base portion by supplying a first graphene raw material onto the base portion, on which the second graphene raw material is supplied, while linearly moving the at least one selected from the display substrate and the nozzle portion facing the display substrate.

In an embodiment, at least one selected from the base portion and the graphene layer may be formed in a pattern.

In an embodiment, the base portion may include at least one selected from polyimide and transition metals.

In an embodiment, the forming the base portion on the display substrate may include supplying a first base raw material onto the display substrate while linearly moving the at least one selected from the display substrate and the nozzle portion facing the display substrate, and supplying a second base raw material onto the display substrate, on which the first base raw material is supplied, while linearly moving the at least one selected from the display substrate and the nozzle portion facing the display substrate.

In an embodiment, the forming the base portion on the display substrate may further include supplying a purge gas onto the display substrate, on which the first base raw material is supplied, while linearly moving the at least one selected from the display substrate and the nozzle portion facing the display substrate.

In an embodiment, the method may further include supplying a purge gas onto the base portion, on which the second graphene raw material is supplied, while linearly moving the at least one selected from the display substrate and the nozzle portion facing the display substrate.

In an embodiment, the method may further include discharging at least one selected from the first graphene raw material and the second graphene raw material.

In an embodiment, the method may further include discharging the second graphene raw material to the outside along a circumference of a planar shape of the nozzle portion.

In an embodiment, these general and specific embodiments may be implemented by using a system, a method, a computer program, or any combination thereof.

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view of an apparatus for manufacturing a display device, according to an embodiment;

FIG. 2 is a schematic cross-sectional view of a nozzle portion shown in FIG. 1;

FIG. 3 is a schematic rear view of the nozzle portion shown in FIG. 1;

FIG. 4 is a schematic perspective view of a portion of an apparatus for manufacturing a display device, according to an alternative embodiment;

FIG. 5 is a schematic perspective view of a portion of an apparatus for manufacturing a display device, according to an alternative embodiment;

FIG. 6 is a schematic plan view of a display device according to an embodiment;

FIG. 7A is a cross-sectional view of the display device of FIG. 6, taken along line D-D′ of FIG. 6;

FIG. 7B is an enlarged view of the encircled portion of FIG. 7A; and

FIGS. 8A and 8B are schematic circuit diagrams of a circuit of the display device shown in FIG. 6.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

“Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the embodiments may have different forms and should not be construed as being limited to the descriptions set forth herein.

One or more embodiments will be described below in detail with reference to the accompanying drawings. Those elements that are the same or are in correspondence with each other are rendered the same reference numeral regardless of the figure number, and redundant descriptions thereof are omitted.

It will be understood that, although the terms “first”, “second”, “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element”, “component”, “region”, “layer” or “section” discussed below could be termed a second element, component, region, layer or section without departing from the teachings herein.

The terminology used herein is for the purpose of describing particular embodiments only and is not intended to be limiting. As used herein, “a”, “an”, “the”, and “at least one” do not denote a limitation of quantity, and are intended to include both the singular and plural, unless the context clearly indicates otherwise. For example, “an element” has the same meaning as “at least one element”, unless the context clearly indicates otherwise. “At least one” is not to be construed as limiting “a” or “an.”

It will be understood that the terms “include”, “comprise”, and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

The direction x, the direction y, and the direction z are not limited to directions corresponding to three axes of the rectangular coordinate system and may be interpreted in a broader sense. For example, the direction x, the direction y, and the direction z may be perpendicular to one another or may represent different directions that are not perpendicular to one another.

Furthermore, relative terms, such as “lower” or “bottom” and “upper” or “top”, may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower”, can therefore, encompasses both an orientation of “lower” and “upper”, depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

When an embodiment may be implemented differently, a certain process order may be performed differently from the described order. For example, two consecutively described processes may be performed substantially at the same time or performed in an order opposite to the described order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

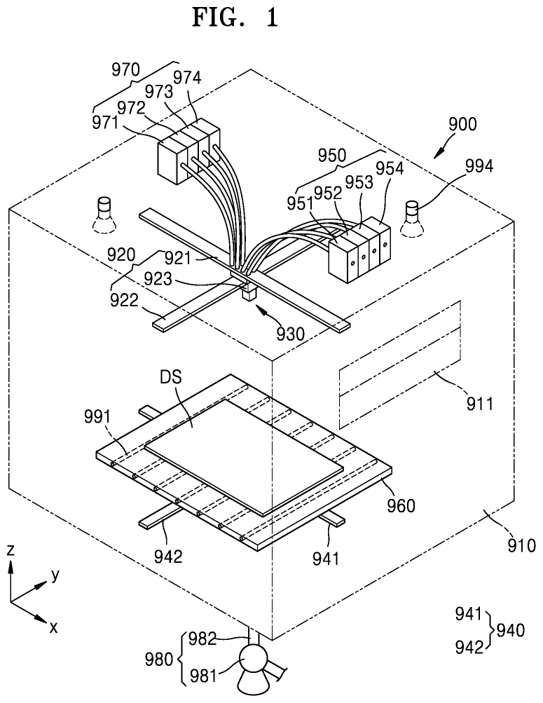

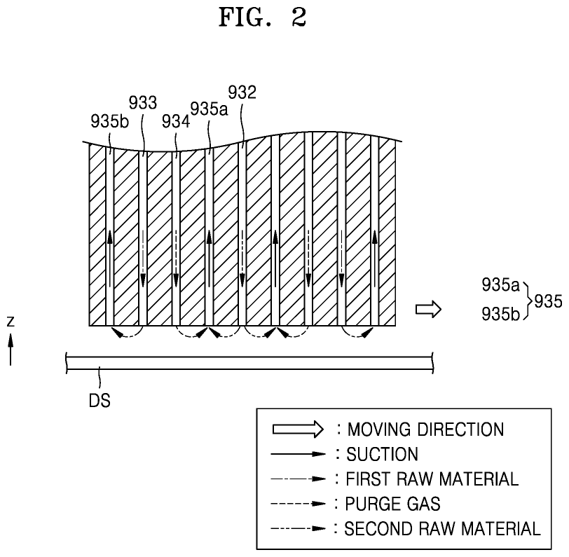

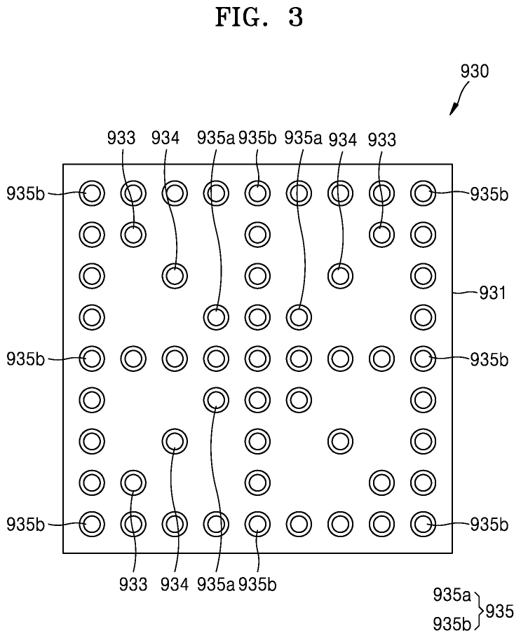

FIG. 1 is a schematic perspective view of an apparatus 900 for manufacturing a display device, according to an embodiment. FIG. 2 is a schematic cross-sectional view of a nozzle portion 930 shown in FIG. 1. FIG. 3 is a schematic rear view of the nozzle portion 930 shown in FIG. 1.

Referring to FIGS. 1 to 3, an embodiment of the apparatus 900 for manufacturing a display device may include a chamber 910, a first driver 920, a nozzle portion 930, a second driver 940, a stage 960, a first raw material supply portion 950, a second raw material supply portion 970, a pressure adjuster 980, a position sensor 994, and an energy generator 991.

The chamber 910 may include or define an internal space therein and be provided with an opening connected to the internal space. A gate valve 911 may be arranged in the opening to open or close the opening.

In an embodiment, a driver (not shown) may linearly move at least one selected from the nozzle portion 930 and the stage 960. In such an embodiment, the driver may allow the nozzle portion 930 and the stage 960 to move relative to each other. Hereinafter, embodiments where the driver includes the first driver 920 and the second driver 940 will be mainly described for convenience.

The first driver 920 may be arranged inside the chamber 910 or may be arranged in the chamber 910. The first driver 920 may move the nozzle portion 930 in at least one direction or in a predetermined direction. In an embodiment, for example, the first driver 920 may linearly move the nozzle portion 930 in a first direction (e.g., one of the direction x, the direction y, and an oblique direction of the direction x or the direction y in FIG. 1). In addition, the first driver 920 may linearly move the nozzle portion 930 in a second direction (e.g., another of the direction x, the direction y, and an oblique direction of the direction x or the direction y in FIG. 1) having a certain angle with respect to the first direction. The first driver 920 may linearly move the nozzle portion 930 in a third direction (e.g., the direction z of FIG. 1) having a certain angle with respect to the first and second directions. The first direction, the second direction, and the third direction may be perpendicular to one another.

The first driver 920 may include a first first driver 921 for guiding (or controlling) motion of the nozzle portion 930 while linearly moving the nozzle portion 930 in the first direction, a second first driver 922 for guiding motion of the nozzle portion 930 while linearly moving the nozzle portion 930 in the second direction, and a third first driver 923 for linearly moving the nozzle portion 930 in the third direction. One of the first first driver 921 and the second first driver 922 may be connected to the other of the first first driver 921 and the second first driver 922. In an embodiment, for example, the first first driver 921 may be connected to the chamber 910, and the second first driver 922 may be connected to the first first driver 921 to move. In an alternative embodiment, the second first driver 922 may be connected to the chamber 910, and the first first driver 921 may be connected to the second first driver 922. Hereinafter, embodiments where the first first driver 921 is connected to the chamber 910 and the second first driver 922 is connected to the first first driver 921 to move will be mainly described for convenience.

The first first driver 921 may have various forms. In an embodiment, for example, the first first driver 921 may include a linear motor. In an alternative embodiment, the first first driver 921 may include a ball screw, a motor connected to the ball screw, and a linear motion guide. In another alternative embodiment, the first first driver 921 may include a cylinder and a linear motion guide. Hereinafter, embodiments where the first first driver 921 includes a linear motor will be mainly described for convenience.

In an embodiment where the first first driver 921 includes a linear motor or a linear motion guide, the second first driver 922 may be arranged at a block that is disposed on a rail in the linear motor or the linear motion guide to move. The second first driver 922 is the same as or similar to the first first driver 921, and thus, any repetitive detailed description thereof will be omitted.

In an embodiment, the third first driver 923 may be connected to the second first driver 922. In such an embodiment, the third first driver 923 may be the same as or similar to the first first driver 921. Hereinafter, embodiments where the third first driver 923 includes a cylinder will be mainly described for convenience.

The nozzle portion 930 may be arranged at the first driver 920 to linearly move in at least one direction. A bottom surface of the nozzle portion 930 facing a display substrate DS may have various shapes. In an embodiment, for example, the bottom surface of the nozzle portion 930 may have a polygonal shape, such as a quadrangular shape, a circular shape, or an oval shape. Hereinafter, embodiments where the bottom surface of the nozzle portion 930 has a square shape will be mainly described for convenience.

The nozzle portion 930 may include a plurality of nozzle portions and a suction portion 935. In an embodiment, for example, the nozzle portion 930 may include a first nozzle portion 932, a second nozzle portion 933, and a third nozzle portion 934 that are arranged in a line. The first nozzle portion 932 may supply a first raw material to the display substrate DS. The first raw material may include a first graphene raw material used to form a graphene layer and a first base raw material used to form a base portion (not shown). The second nozzle portion 933 may supply a second raw material to the display substrate DS. The second raw material may include a second graphene raw material used to form the graphene layer and a second base raw material used to form the base portion. The second nozzle portion 933 may include at least one second nozzle portion 933. In an embodiment where the second nozzle portion 933 includes a plurality of second nozzle portions 933, the plurality of second nozzle portions 933 may be arranged in a line. The plurality of second nozzle portions 933 may be arranged between the third nozzle portion 934 and a second suction portion 935b described below.

The third nozzle portion 934 may supply a purge gas to the display substrate DS. In an embodiment, the purge gas may include inert gases, such as hydrogen, argon, and helium. The first base raw material may include a polyimide precursor or a transition metal precursor, and the second base raw material may include a reducing material, such as hydrogen. In an embodiment, the first base raw material, which is in a liquid form, may be heated and vaporized and thus supplied to the nozzle portion 930.

A planar shape of at least one selected from the first nozzle portion 932, the second nozzle portion 933, and the third nozzle portion 934 may be a circular shape, and a diameter of the planar shape of at least one selected from the first nozzle portion 932, the second nozzle portion 933, and the third nozzle portion 934 may be about 0.5 micrometer (μm) or greater and about 100 μm or less. For example, at least one selected from the first nozzle portion 932, the second nozzle portion 933, and the third nozzle portion 934 may be provided with a hole having a diameter of 0.5 μm or greater and 100 μm or less. In a case where the diameter of the planar shape of at least one of the first nozzle portion 932, the second nozzle portion 933, and the third nozzle portion 934 is less than about 0.5 μm, pressure or velocity of injected gas may be excessive, and thus, a portion of the display substrate DS may be damaged. In a case where the diameter of the planar shape of at least one of the first nozzle portion 932, the second nozzle portion 933, and the third nozzle portion 934 is greater than about 100 μm, a graphene layer formed on the display substrate DS may not be formed in a fine pattern, or since a graphene layer is formed to overlap another layer, it may be difficult to form a precise graphene layer.

The first nozzle portion 932, the second nozzle portion 933, and the third nozzle portion 934 may be adjacent to one another. The first nozzle portion 932 and the third nozzle portion 934 may be adjacent to each other. In addition, the second nozzle portion 933 and the third nozzle portion 934 may be adjacent to each other. The third nozzle portion 934 may be arranged between the first nozzle portion 932 and the second nozzle portion 933.

The nozzle portion 930 may include the suction portion 935. The suction portion 935 may suck in at least one selected from a first raw material gas, a second raw material gas, and a purge gas and discharge the same to the outside. The suction portion 935 may include at least one suction portion 935. A plurality of suction portions 935 may include a first suction portion 935a and a second suction portion 935b. The first suction portion 935a may be arranged between the first nozzle portion 932 and the third nozzle portion 934. The second suction portion 935b may be arranged at an outer edge of a planar shape of the nozzle portion 930. The second suction portion 935b may include a plurality of second suction portions 935b, and as shown in FIG. 3, the plurality of second suction portions 935b may surround the edge of the planar shape of the nozzle portion 930. As shown in FIG. 3, the first nozzle portion 932, a plurality of second nozzle portion 933, the third nozzle portion 934, and the first suction portion 935a may be arranged inside an arbitrary closed loop in which a plurality of second suction portions 935b is arranged.

Accordingly, the second suction portion 935b may effectively prevent gases supplied from the first nozzle portion 932, the second nozzle portion 933, and the third nozzle portion 934 from being discharged outside the edge of the nozzle portion 930, thereby reducing the gases from being arranged at a portion other than a portion where the nozzle portion 930 is arranged.

In an embodiment, the second suction portion 935b, the second nozzle portion 933, the third nozzle portion 934, the first suction portion 935a, the first nozzle portion 932, the first suction portion 935a, the third nozzle portion 934, the second nozzle portion 933, and the second suction portion 935b may be arranged in a line with respect to a moving direction of the nozzle portion 930 or a moving direction of the display substrate DS. The arrangement of each of the first nozzle portion 932, the second nozzle portion 933, and the third nozzle portion 934, described above is not limited thereto. In an embodiment, for example, when at least one selected from the first nozzle portion 932 and the second nozzle portion 933 is provided in plural, a plurality of first nozzle portions 932 may be arranged to correspond to a portion where one first nozzle portion 932 shown in FIG. 2 is arranged, and a plurality of second nozzle portions 933 may be arranged to correspond to a portion where one second nozzle portion 933 shown in FIG. 2 is arranged. In an alternative embodiment, the second nozzle portion 933, the third nozzle portion 934, the first suction portion 935a, the first nozzle portion 932, the first suction portion 935a, the third nozzle portion 934, and the second nozzle portion 933 may constitute one group, and such a group may be arranged in a plurality of numbers between second suction portions 935b apart from each other.

The second driver 940 may move the stage 960 in at least one direction. The second driver 940 may include a first second driver 941 and a second second driver 942 connected to each other. The first second driver 941 may move the stage 960 in the first direction. The second second driver 942 may move the stage 960 in the second direction. In an embodiment, the first second driver 941 and the second second driver 942 may have the same or similar form as the first first driver 921 described above.

One or more embodiments are illustrated as including both of the first driver 920 and the second driver 940 but are not limited thereto. In an alternative embodiment, for example, the apparatus 900 for manufacturing a display device may include only one of the first driver 920 and the second driver 940. Hereinafter, embodiments where the apparatus 900 for manufacturing a display device includes the first driver 920 and the second driver 940 will be mainly described for convenience.

The stage 960 may be seated on the second driver 940 to linearly move. The stage 960 may be connected to the first second driver 941 or the second second driver 942. In an embodiment where the first second driver 941 and the stage 960 are connected to each other, the first second driver 941 may be disposed on the second second driver 942 and connected to the second second driver 942. In an alternative embodiment, where the second second driver 942 and the stage 960 are connected to each other, the second second driver 942 may be disposed on the first second driver 941 and connected to the first second driver 941. Hereinafter, embodiments where the first second driver 941 is disposed on the second second driver 942 and the stage 960 is disposed on the first second driver 941 will be mainly described for convenience.

In addition to being linearly moved by the second driver 940, the stage 960 may include a separate driver and thus may be fine-adjusted. In an embodiment, for example, the stage 960 may be an align stage. The align stage may perform a motion, such as rotation or elevation.

The first second driver 941 and the stage 960 may linearly move in the second direction based on the operation of the second second driver 942. In addition, the stage 960 may linearly move in the first direction based on the operation of the first second driver 941.

The first raw material supply portion 950 may supply gas for forming the base portion on the display substrate DS to the nozzle portion 930. The first raw material supply portion 950 may include a plurality of first raw material supply portions 950, and each first raw material supply portion 950 may be connected to the nozzle portion 930 through a different pipe. The plurality of first raw material supply portions 950 may include a first first raw material supply portion 951 for supplying a first base raw material, a second first raw material supply portion 952 for supplying a second base raw material, a first purge gas supply portion 953 for supplying a purge gas, and a first suction driver 954 for discharging gas to the outside. The first first raw material supply portion 951, the second first raw material supply portion 952, and the first purge gas supply portion 953 may each include a storage portion for storing gas, a pump connected to the storage portion to move gas inside the storage portion, and a valve disposed on a pipe to selectively open and close the pipe. In addition, the first suction driver 954 may include a pump and thus may suck in gas between the display substrate DS and the nozzle portion 930 through the first suction portion 935a and discharge the gas to the outside.

The second raw material supply portion 970 may supply gas for forming a graphene layer (not shown) on the display substrate DS to the nozzle portion 930. The second raw material supply portion 970 may include a plurality of second raw material supply portions 970, and each second raw material supply portion 970 may be connected to the nozzle portion 930 through a different pipe. The plurality of second raw material supply portions 970 may include a first second raw material supply portion 971 for supplying a first graphene raw material, a second second raw material supply portion 972 for supplying a second graphene raw material, a second purge gas supply portion 973 for supplying a purge gas, and a second suction driver 974 for discharging gas to the outside. The first second raw material supply portion 971, the second second raw material supply portion 972, and the second purge gas supply portion 973 may be the same as or similar to the first first raw material supply portion 951, the second first raw material supply portion 952, and the first purge gas supply portion 953, respectively. In addition, the second suction driver 974 may be the same as or similar to the first suction driver 954 described above.

In the above case, the first first raw material supply portion 951 and the first second raw material supply portion 971 may be connected to the first nozzle portion 932, and the second first raw material supply portion 952 and the second second raw material supply portion 972 may be connected to the second nozzle portion 933. The first purge gas supply portion 953 and the second purge gas supply portion 973 may be connected to the third nozzle portion 934, and the first suction driver 954 and the second suction driver 974 may be connected to the first suction portion 935a and the second suction portion 935b, respectively.

The pressure adjuster 980 may be connected to the chamber 910. The pressure adjuster 980 may guide gas inside the chamber 910 to the outside. In an embodiment, for example, the pressure adjuster 980 may include a guide pipe 982 connected to the chamber 910 and a pump 981 disposed on the guide pipe 982. The pressure adjuster 980 may maintain internal pressure of the chamber 910 at a level that is lower than atmospheric pressure by discharging gas inside the chamber 910 to the outside.

The position sensor 994 may be arranged outside the chamber 910 or inside the chamber 910 or may be disposed through the chamber 910. The position sensor 994 may include a camera and may capture a position of the display substrate DS disposed on the stage 960. In addition, the position sensor 994 may capture a position of the nozzle portion 930. The position sensor 994 may include at least one position sensor 994, and in an embodiment where the position sensor 994 includes a plurality of position sensors 994, the plurality of position sensors 994 may be apart from each other. A position of the display substrate DS may be adjusted through an image of the display substrate DS captured by each position sensor 994 or an alignment mark disposed on the display substrate DS.

The energy generator 991 may include a heater arranged outside the stage 960 or arranged inside the stage 960 to apply convective heat or radiant heat. In an embodiment, the energy generator 991 may include the form of a coil or metal bar inserted into the stage 960. The coil or metal bar may generate heat when electricity is applied thereto. In an alternative embodiment, the energy generator 991 may include a pipe having a space therein and may include a heat medium circulating through the pipe. In another alternative embodiment, the energy generator 991 may be apart from the stage 960 and may heat the display substrate DS. In such an embodiment, the energy generator 991 may be disposed above the stage 960 or may be disposed below the stage 960. Hereinafter, embodiments where the energy generator 991 is in the form of a coil or metal bar will be mainly described in detail for convenience.

The graphene layer may be disposed or formed on the display substrate DS through the apparatus 900 for manufacturing a display device.

In an embodiment, the pressure adjuster 980 may make internal pressure of the chamber 910 the same as or similar to atmospheric pressure. After opening the gate valve 911 of the chamber 910, the display substrate DS may be disposed on the stage 960. Although not shown, the display substrate DS may be brought into the chamber 910 through a separate robot arm or shuttle arranged outside the chamber 910.

After the display substrate DS is disposed on the stage 960, a position of the display substrate DS may be captured through the position sensor 994. A position of the stage 960 may be fine-adjusted based on the position of the display substrate DS captured by the position sensor 994, which may allow a posture of the display substrate DS to correspond to a previously set posture.

By operating at least one of the first driver 920 and the second driver 940, at least one selected from a position of the nozzle portion 930 and a position of the display substrate DS may be set at an initial working position.

While the nozzle portion 930 and the display substrate DS are moved relative to each other, the base portion may be disposed on the display substrate DS by the nozzle portion 930. In an embodiment, for example, while the second driver 940 does not operate, the first driver 920 may operate to linearly move the nozzle portion 930 in at least one selected from the first direction and the second direction. In such an embodiment, the stage 960 may be stationary. In an alternative embodiment, while the first driver 920 does not operate, the second driver 940 may operate to linearly move the stage 960 in at least one selected from the first direction and the second direction. In such an embodiment, the nozzle portion 930 may be stationary. In another alternative embodiment, the first driver 920 and the second driver 940 may operate to linearly move each of the nozzle portion 930 and the stage 960 individually in at least one selected from the first direction and the second direction. In such an embodiment, the nozzle portion 930 and the stage 960 may have been previously set to respectively move along previously set paths of operation of the first driver 920 and the second driver 940. Hereinafter, embodiments where the stage 960 remains stationary and the nozzle portion 930 linearly moves in a direction of the arrow shown in FIG. 2 will be mainly described in detail for convenience.

The nozzle portion 930 may form the base portion on the display substrate DS. In an embodiment, the second raw material supply portion 970 may supply a first base raw material, a second base raw material, and a purge gas to the nozzle portion 930.

When the nozzle portion 930 forms the base portion, the display substrate DS may sequentially pass below the second suction portion 935b, the second nozzle portion 933, the third nozzle portion 934, the first suction portion 935a, the first nozzle portion 932, the first suction portion 935a, the third nozzle portion 934, the second nozzle portion 933, and the second suction portion 935b. In such an embodiment, the second base raw material supplied from the second nozzle portion 933 may be first supplied onto the display substrate DS, the purge gas and the first base raw material may be sequentially supplied, and the second base raw material may be supplied again. In such an embodiment, the purge gas may effectively prevent the second base raw material or the first base raw material from being excessively concentrated on the display substrate DS. In such an embodiment, the base portion may be disposed on a portion of the display substrate DS, and thus, the base portion in the form of a pattern may be disposed on the display substrate DS.

While the above process is in progress, the second suction driver 974 may suck in gas from the edge of the nozzle portion 930 and the inside of the edge of the nozzle portion 930 and discharge the gas to the outside. In an embodiment, by sucking in gas through the second suction portion 935b, the first base raw material, the second base raw material, and the purge gas may be effectively prevented from moving to another portion of the display substrate DS other than a portion of the display substrate DS facing the nozzle portion 930.

In an embodiment, while the above process is in progress, the energy generator 991 may apply heat to the stage 960. Through the heat, the first base raw material and the second base raw material may react with each other to form the base portion. The pressure adjuster 980 may discharge gas inside the chamber 910 to the outside.

When the above process is completed, at least one selected from the first driver 920 and the second driver 940 may operate to arrange at least one selected from the display substrate DS and the nozzle portion 930 in a way such that relative positions of the display substrate DS and the nozzle portion 930 are the same as or similar to an initial position.

Thereafter, the first raw material supply portion 950 may supply a first graphene layer raw material, a second graphene layer raw material, and a purge gas to the nozzle portion 930. The nozzle portion 930 may sequentially supply the second graphene layer raw material, the purge gas, the first graphene layer raw material, the purge gas, and the second graphene layer raw material to the display substrate DS through the second nozzle portion 933, the third nozzle portion 934, the first nozzle portion 932, the third nozzle portion 934, and the second nozzle portion 933 that are sequentially arranged. In addition, the first suction portion 935a may suck in the first graphene layer raw material and the purge gas, and the second suction portion 935b may suck in the second graphene layer raw material. The first graphene layer raw material may be a material including titanium (TI), such as tetrakis(dimethylamino)titanium(IV) (TDMAT), etc. In addition, the second graphene layer raw material may be a material including carbon (C), such as methane (CH₄), ethylene (C₂H₄), etc. In this case, the first graphene layer raw material and the second graphene layer raw material may be supplied to the nozzle portion 930 in a gaseous form. In addition, at least one selected from the first graphene raw material and the second graphene raw material may be discharged. For example, the second graphene raw material may be discharged to the outside along a circumference of a planar shape of the nozzle portion 930.

The first graphene layer raw material, the purge gas, and the second graphene layer raw material may be supplied onto the display substrate DS as described above to arrange the graphene layer. In an embodiment, the energy generator 991 may heat the display substrate DS by heating the stage 960. In addition, the pressure adjuster 980 may discharge gas inside the chamber 910 to the outside. The nozzle portion 930 may form the graphene layer on a top surface of the base portion by moving along a top surface of the display substrate DS on which the base portion is disposed. The graphene layer may be formed on the top surface of the base portion and thus may be disposed on the display substrate DS in a pattern that is the same as or similar to that of the base portion.

The display substrate DS on which the graphene layer and the base portion are disposed as described above may be taken out of the chamber 910 or may have another process performed thereon in another space inside the chamber 910.

Accordingly, in embodiments of the apparatus 900 for manufacturing a display device and a method of manufacturing a display device, a graphene layer having a precise pattern may be provided or formed on the display substrate DS. In addition, in embodiments of the apparatus 900 for manufacturing a display device and a method of manufacturing a display device, a transfer method is not used when forming the graphene layer, and thus, the process order may be simple and processes may be finely or precisely performed.

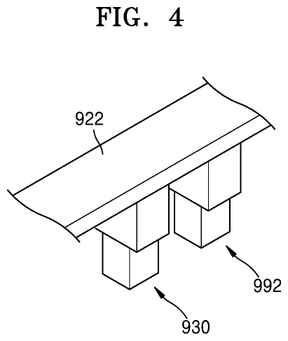

FIG. 4 is a schematic perspective view of a portion of the apparatus 900 for manufacturing a display device, according to an alternative embodiment.

Referring to FIG. 4, an embodiment of the apparatus 900 for manufacturing a display device may include a chamber (not shown), a first driver (not shown), the nozzle portion 930, a second driver (not shown), a stage (not shown), a first raw material supply portion (not shown), a second raw material supply portion (not shown), a pressure adjuster (not shown), a position sensor (not shown), and an energy generator 992. In such an embodiment, the chamber, the first driver, the nozzle portion 930, the second driver, the stage, the first raw material supply portion, the second raw material supply portion, the pressure adjuster, and the position sensor are the same as or similar to those described above with reference to FIGS. 1 to 3, and thus, any repetitive detailed description thereof will be omitted.

The energy generator 992 may include a light source portion including a light source connected to the nozzle portion 930 to emit light toward the display substrate DS. The light source may emit ultraviolet rays. In an embodiment, the energy generator 992 may move together with the nozzle portion 930 or may independently move separately from the nozzle portion 930. For example, the light source portion of the energy generator 992 may be arranged at the nozzle portion 930 or apart from the nozzle portion 930, wherein the light source portion linearly moves in a predetermined direction and emits light to the display substrate DS. Hereinafter, embodiments where the energy generator 992 moves together with the nozzle portion 930 will be mainly described for convenience.

As described above with reference to FIGS. 1 to 3, the energy generator 992 may provide energy when the base portion and the graphene layer are formed.

Accordingly, in embodiments of the apparatus 900 for manufacturing a display device and a method of manufacturing a display device, a graphene layer may be directly formed on a display substrate DS. In addition, in embodiments of the apparatus 900 for manufacturing a display device and a method of manufacturing a display device, a graphene layer having a pattern (or a patterned shape) may be provided on a display substrate DS.

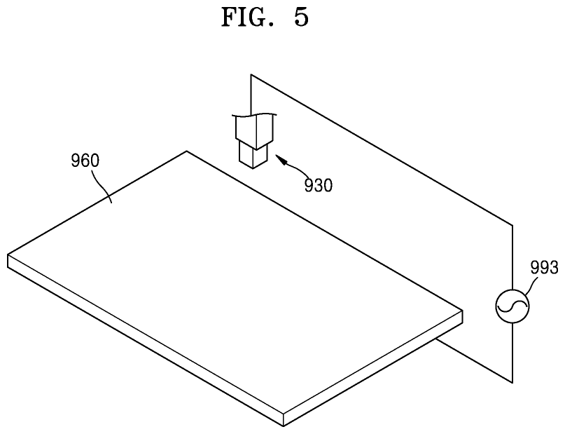

FIG. 5 is a schematic perspective view of a portion of the apparatus 900 for manufacturing a display device, according to an alternative embodiment.

Referring to FIG. 5, an embodiment of the apparatus 900 for manufacturing a display device may include a chamber (not shown), a first driver (not shown), the nozzle portion 930, a second driver (not shown), the stage 960, a first raw material supply portion (not shown), a second raw material supply portion (not shown), a pressure adjuster (not shown), a position sensor (not shown), and an energy generator 993. In such an embodiment, the chamber, the first driver, the nozzle portion 930, the second driver, the stage 960, the first raw material supply portion, the second raw material supply portion, the pressure adjuster, and the position sensor are the same as or similar to those described above with reference to FIGS. 1 to 3, and thus, any repetitive detailed description thereof will be omitted.

The energy generator 993 may include a power supply portion electrically connected to each of the nozzle portion 930 and the stage 960 to generate an alternating current. When the energy generator 993 operates, a voltage difference may occur between the nozzle portion 930 and the stage 960, and when gas is supplied between the nozzle portion 930 and the stage 960 from the nozzle portion 930, the gas may be converted into plasma. Thus, the energy generator 993 may provide energy for each raw material to react with one another.

Accordingly, in embodiments of the apparatus 900 for manufacturing a display device and a method of manufacturing a display device, a graphene layer may be directly formed on a display substrate DS. In addition, in embodiments of the apparatus 900 for manufacturing a display device and a method of manufacturing a display device, a graphene layer having a pattern may be disposed on a display substrate DS.

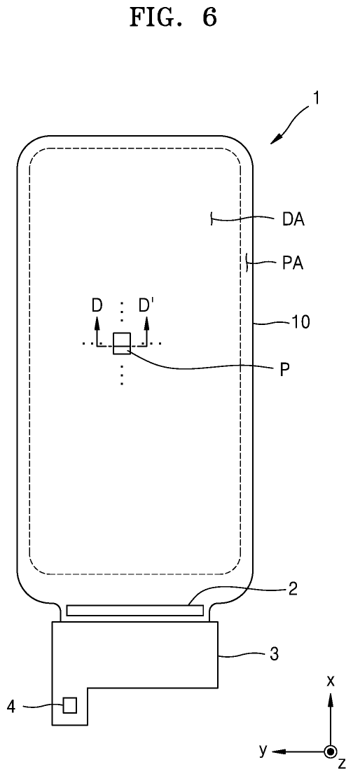

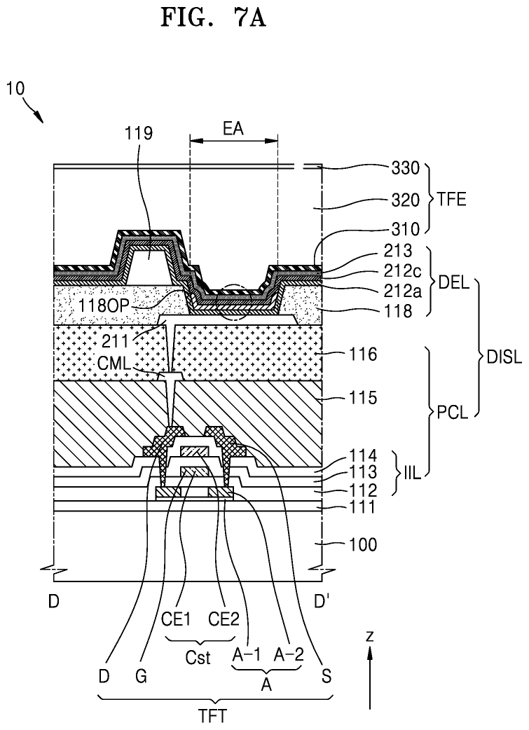

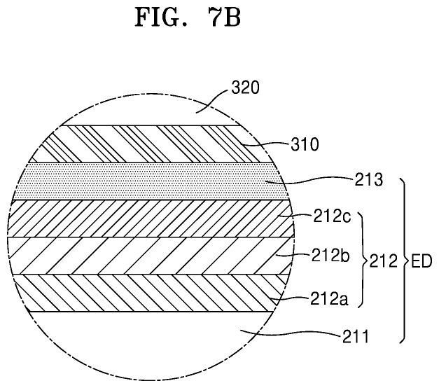

FIG. 6 is a schematic plan view of a display device 1 according to an embodiment. FIG. 7A is a cross-sectional view of the display device 1 of FIG. 6, taken along line D-D′ of FIG. 6. FIG. 7B is an enlarged view of the encircled portion of FIG. 7A. FIG. 7A is a schematic cross-sectional view of a portion of the display device 1 shown in FIG. 6.

Referring to FIGS. 6, 7A and 7B, an embodiment of the display device 1 may further include a display panel 10, a display circuit board 3, a display driver 2, and a touch sensor driver 4. The display panel 10 may be a light-emitting display panel including a display element (a light-emitting element). In an embodiment, for example, the display panel 10 may be an organic light-emitting display panel using an organic light-emitting diode including an organic emission layer, a micro light-emitting diode (LED) display panel using a micro LED, a quantum-dot light-emitting display panel using a quantum-dot light-emitting diode including a quantum-dot emission layer, or an inorganic light-emitting display panel using an inorganic light-emitting diode including an inorganic semiconductor.

The display panel 10 may be a transparent display panel which is transparent such that an object or background arranged on a bottom surface of the display panel 10 may be viewed through a top surface of the display panel 10. Alternatively, the display panel 10 may be a reflective display panel which may reflect an object or background on a top surface of the display panel 10.

The display panel 10 may include a display area DA in which an image is displayed and a peripheral area PA surrounding the display area DA. A separate driving circuit, a pad, etc. may be arranged in the peripheral area PA.

In an embodiment, the peripheral area PA may include a pad area (not indicated).

The pad area may protrude from the peripheral area PA on one side of the display panel 10 in a direction −x. The display driver 2 may be arranged in the pad area, and the display circuit board 3 may be connected thereto.

In an embodiment, the display panel 10 may include a bending area (not shown) arranged between the pad area and the display area DA and bent. The display panel 10 may be bent in the bending area, and the pad area may be disposed over a bottom surface of a panel protection member. The pad area may overlap the display area DA in a thickness direction (a direction z) of the display panel 10. In an embodiment, the pad area may be fixed to the panel protection member through a panel adhesion member (not shown). The panel adhesion member may be a pressure-sensitive adhesive.

In an alternative embodiment, the peripheral area PA may not include the bending area. In such an embodiment, a flexible film may be bent, or the display circuit board 3 may be bent. In such an embodiment, the panel adhesion member may be arranged in the same or similar manner as described above.

In an alternative embodiment, neither the display panel 10 nor the display circuit board 3 may be bent.

The display area DA may include a plurality of pixels, which are display elements, and an image may be displayed through the plurality of pixels. Each of the plurality of pixels may include sub-pixels. In an embodiment, for example, each of the plurality of pixels may include a red sub-pixel, a green sub-pixel, and a blue sub-pixel. Alternatively, each of the plurality of pixels may include a red sub-pixel, a green sub-pixel, a blue sub-pixel, and a white sub-pixel.

The display circuit board 3 may be attached to one side edge of the display panel 10.

The display driver 2 may be disposed on various portions. In an embodiment, for example, the display driver 2 may be disposed on a substrate 100 of the display panel 10. In an alternative embodiment, the display driver 2 may be disposed on a flexible film. In an alternative embodiment, the display driver 2 may be disposed on the display circuit board 3. Hereinafter, embodiments where the display driver 2 is disposed on the substrate 100 will be mainly described for convenience.

The display driver 2 may receive control signals and power voltages and may generate and output signals and voltages for driving the display panel 10. The display driver 2 may be formed as an integrated circuit (IC).

The display circuit board 3 may be attached to the display panel 10. In an embodiment, the display circuit board 3 and the display panel 10 may be connected to each other in various ways. In an embodiment, the display circuit board 3 and the display panel 10 may be attached to each other by using a flexible film. In such an embodiment, the flexible film may be connected to the display panel 10 and the display circuit board 3 through an anisotropic conductive film. The display circuit board 3 may be a flexible printed circuit board (FPCB) which is bendable, or a hybrid printed circuit board including both of a rigid printed circuit board (rigid PCB) which is solid and not easy to bend and an FPCB.

In an alternative embodiment, one side of the display circuit board 3 may be directly attached to one side edge of the display panel 10 by using an anisotropic conductive film. Hereinafter, embodiments where the display circuit board 3 and the display panel 10 are connected to each other through an anisotropic conductive film will be mainly described for convenience.

The touch sensor driver 4 may be disposed on the display circuit board 3. The touch sensor driver 4 may be formed as an IC. The touch sensor driver 4 may be attached on the display circuit board 3. The touch sensor driver 4 may be electrically connected to touch electrodes of a touchscreen layer of the display panel 10 through the display circuit board 3.

The touchscreen layer may be disposed on a thin-film encapsulation layer TFE of the display panel 10. In an embodiment, the touchscreen layer may sense a user's touch input by using at least one of various touch methods, such as a resistive method and a capacitive method. In an embodiment, for example, where the touchscreen layer of the display panel 10 senses a user's touch input in a capacitive manner, the touch sensor driver 4 may apply driving signals to driving electrodes among the touch electrodes and may sense, through sensing electrodes among the touch electrodes, voltages charged in mutual capacitances between the driving electrodes and the sensing electrodes, thereby determining whether there is a user's touch. The user's touch may include a contact touch and a proximity touch. The contact touch refers to direct contact of a user's finger or an object, such as a pen, with a cover member disposed on the touchscreen layer. The proximity touch refers to a user's finger or an object, such as a pen, being positioned above and closely apart from the cover member, such as hovering. The touch sensor driver 4 may transmit sensor data corresponding to the sensed voltages to a main processor, and the main processor may analyze the sensor data to calculate touch coordinates where the touch input is made.

A power supply unit for supplying driving voltages for driving the pixels of the display panel 10, a scan driver, and the display driver 2 may be additionally disposed on the display circuit board 3. Alternatively, the power supply unit may be integrated with the display driver 2, and in such an embodiment, the display driver 2 and the power supply unit may be formed as a single IC.

The display panel 10 may include the substrate 100 and a display layer DISL.

The display layer DISL may be disposed on the substrate 100. The display layer DISL may include pixels, and may be a layer for displaying an image. The display layer DISL may include a circuit layer including thin-film transistors, a display element layer in which display elements are arranged, and an encapsulation member for encapsulating the display element layer.

The display layer DISL may be divided into the display area DA and the peripheral area PA. The display area DA may be an area in which pixels are arranged to display an image. The peripheral area PA may be an area arranged outside the display area DA and where no image is displayed. The peripheral area PA may surround the display area DA. The peripheral area PA may be an area from the outside of the display area DA to the edge of the display panel 10. Not only pixels but also pixel circuits for driving the pixels, scan lines, data lines and power lines connected to the pixel circuits, or the like may be arranged in the display area DA. A scan driver for applying scan signals to the scan lines, fan-out lines connecting the data lines and the display driver 2 to each other, or the like may be arranged in the peripheral area PA.

The touchscreen layer may be disposed on the display layer DISL. The touchscreen layer may include touch electrodes, and may be a layer for sensing whether a user's touch is made. The touchscreen layer may be directly formed on the encapsulation member of the display layer DISL. Alternatively, the touchscreen layer may be separately formed and then coupled onto the encapsulation member of the display layer DISL through an adhesive layer, such as an optically clear adhesive (OCA).

The display panel 10 may include the substrate 100, a buffer layer 111, the display layer DISL, and the thin-film encapsulation layer TFE. The display layer DISL may include a pixel circuit layer PCL and a display element layer DEL.

The substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, etc. The substrate 100 including polymer resin may be flexible, rollable and/or bendable. The substrate 100 may have a multi-layer structure including a base layer and a barrier layer (not shown), where the base layer includes at least one selected from the above-described polymer resins.

The buffer layer 111 may include an inorganic insulating material, such as silicon nitride, silicon oxynitride, and silicon oxide, and may have a single-layer or multi-layer structure including at least one selected from the above-described inorganic insulating materials.

The pixel circuit layer PCL may be disposed on the buffer layer 111. The pixel circuit layer PCL may include a thin-film transistor TFT included in a pixel circuit, and an inorganic insulating layer IIL, a first planarization layer 115, and a second planarization layer 116 disposed below and/or over elements of the thin-film transistor TFT. The inorganic insulating layer IIL may include a first gate insulating layer 112, a second gate insulating layer 113, and an interlayer insulating layer 114.

The thin-film transistor TFT may include a semiconductor layer A, and the semiconductor layer A may include polysilicon. Alternatively, the semiconductor layer A may include amorphous silicon, an oxide semiconductor, or an organic semiconductor. Alternatively, the semiconductor layer A may include a base portion A-1 and a graphene layer A-2. In such an embodiment, a display substrate DS may include the substrate 100 and the buffer layer 111, as shown in FIG. 7A. Hereinafter, embodiments where the semiconductor layer A includes the graphene layer A-2 will be mainly described for convenience.

The base portion A-1 may include at least one selected from polyimide and transition metals, such as nickel (Ni), cobalt (Co), rubidium (Ru), copper (Cu), and platinum (Pt). In such an embodiment, the base portion A-1 and the graphene layer A-2 may be formed through an apparatus 900 for manufacturing a display device described above with reference to FIGS. 1 to 3, FIG. 4 or FIG. 5. Hereinafter, embodiments where the semiconductor layer A includes the base portion A-1 and the graphene layer A-2 will be mainly described for convenience.

In an embodiment where the semiconductor layer A includes the graphene layer A-2, the graphene layer A-2 may be made to have properties similar to those of a semiconductor by doping the graphene layer A-2 with a separate impurity or cutting some of the bonds between carbons of the graphene layer A-2 through plasma treatment.

The semiconductor layer A may include a channel region, and a drain region and a source region respectively disposed on opposing sides of the channel region. A gate electrode G may overlap the channel region.

The semiconductor layer A described above may not be disposed on the entire surface of the substrate 100 but may be disposed on only a certain portion of the substrate 100 to form a pattern.

The gate electrode G may include a low-resistance metal material. The gate electrode G may include a conductive material including molybdenum (Mo), aluminum (Al), copper (Cu), titanium (Ti), etc., and may have a multi-layer or single-layer structure including at least one selected from the above-described materials.

The first gate insulating layer 112 between the semiconductor layer A and the gate electrode G may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Here, zinc oxide (ZnOₓ) may be zinc oxide (ZnO) and/or zinc peroxide (ZnO₂).

The second gate insulating layer 113 may cover the gate electrode G. Similarly to the first gate insulating layer 112, the second gate insulating layer 113 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Here, zinc oxide (ZnOₓ) may be zinc oxide (ZnO) and/or zinc peroxide (ZnO₂).

A top electrode CE2 of a storage capacitor Cst may be disposed on the second gate insulating layer 113. The top electrode CE2 may overlap the gate electrode G therebelow. In an embodiment, the gate electrode G and the top electrode CE2 overlapping each other with the second gate insulating layer 113 therebetween may constitute the storage capacitor Cst of the pixel circuit. That is, the gate electrode G may serve as a bottom electrode CE1 of the storage capacitor Cst. As such, the storage capacitor Cst and the thin-film transistor TFT may overlap each other. In some embodiments, the storage capacitor Cst may not overlap the thin-film transistor TFT.

The top electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and/or copper (Cu), and may have a single-layer or multi-layer structure including at least one selected from the above-described materials.

The interlayer insulating layer 114 may cover the top electrode CE2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Here, zinc oxide (ZnOₓ) may be zinc oxide (ZnO) and/or zinc peroxide (ZnO₂). The interlayer insulating layer 114 may have a single-layer or multi-layer structure including at least one selected from the above-described inorganic insulating materials.

A drain electrode D and a source electrode S may each be on the interlayer insulating layer 114. The drain electrode D and the source electrode S may each include a highly conductive material. The drain electrode D and the source electrode S may each include a conductive material including at least one of molybdenum (Mo), aluminum (Al), copper (Cu), titanium (Ti), etc., and may have a multi-layer or single-layer structure including at least one selected from the above-described materials. In an embodiment, the drain electrode D and the source electrode S may each have a multi-layer structure of titanium (Ti)/aluminum (Al)/titanium (Ti).

The first planarization layer 115 may cover the drain electrode D and the source electrode S. The first planarization layer 115 may include an organic insulating layer. The first planarization layer 115 may include an organic insulating material, such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

A connection electrode CML may be disposed on the first planarization layer 115. In an embodiment, the connection electrode CML may be connected to the drain electrode D or the source electrode S through a contact hole defined in the first planarization layer 115. The connection electrode CML may include a highly conductive material. The connection electrode CML may include a conductive material including at least one of molybdenum (Mo), aluminum (Al), copper (Cu), titanium (Ti), etc., and may have a multi-layer or single-layer structure including at least one selected from the above-described materials. In an embodiment, the connection electrode CML may have a multi-layer structure of titanium (Ti)/aluminum (Al)/titanium (Ti).

The second planarization layer 116 may cover the connection electrode CML. The second planarization layer 116 may include an organic insulating layer. The second planarization layer 116 may include an organic insulating material, such as a general commercial polymer, such as PMMA or PS, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The display element layer DEL may be disposed on the pixel circuit layer PCL. The display element layer DEL may include a display element ED. The display element ED may be an organic light-emitting diode (OLED). A pixel electrode 211 of the display element ED may be electrically connected to the connection electrode CML through a contact hole defined in the second planarization layer 116.

In an embodiment, the pixel electrode 211 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an alternative embodiment, the pixel electrode 211 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an alternative embodiment, the pixel electrode 211 may further include a layer formed of ITO, IZO, ZnO, or In₂O₃ on/under the above-described reflective layer.

A pixel-defining layer 118 with an opening 118OP defined therethrough to expose a central portion of the pixel electrode 211 may be disposed on the pixel electrode 211. The pixel-defining layer 118 may include an organic insulating material and/or an inorganic insulating material. The opening 118OP may define an emission area of light emitted from the display element ED (hereinafter referred to as an emission area EA). In an embodiment, for example, a width of the opening 118OP may correspond to a width of the emission area EA of the display element ED.

A spacer 119 may be disposed on the pixel-defining layer 118. The spacer 119 may be used to prevent destruction of the substrate 100 in a method of manufacturing a display device. A mask sheet may be used to manufacture a display panel 10, and in this regard, failure may be prevented in which the mask sheet enters the opening 118OP of the pixel-defining layer 118 or comes into close contact with the pixel-defining layer 118 and thus a portion of the substrate 100 is damaged or cracked by the mask sheet when a deposition material is deposited on the substrate 100.

The spacer 119 may include an organic insulating material, such as polyimide. Alternatively, the spacer 119 may include an inorganic insulating material, such as silicon nitride or silicon oxide, or may include an organic insulating material and an inorganic insulating material.

In an embodiment, the spacer 119 may include a different material than the pixel-defining layer 118. Alternatively, in another embodiment, the spacer 119 may include a same material as the pixel-defining layer 118, and in such an embodiment, the pixel-defining layer 118 and the spacer 119 may be formed together in a mask process using a halftone mask, etc.

In an embodiment, as shown in FIG. 7B, an intermediate layer 212 may be disposed on the pixel-defining layer 118. The intermediate layer 212 may include an emission layer 212b arranged in the opening 118OP of the pixel-defining layer 118. The emission layer 212b may include a polymer organic material or low-molecular weight organic material emitting light of a certain color.

A first functional layer 212a and a second functional layer 212c may be disposed under and on the emission layer 212b, respectively. The first functional layer 212a may include, for example, a hole transport layer (HTL), or both of an HTL and a hole injection layer (HIL). The second functional layer 212c is an element disposed on the emission layer 212b and may be optional. The second functional layer 212c may include an electron transport layer (ETL) and/or an electron injection layer (EIL). The first functional layer 212a and/or the second functional layer 212c may be a common layer that covers the entire substrate 100 as an opposite electrode 213 described below does.

The opposite electrode 213 may include a conductive material having a low work function. In an embodiment, for example, the opposite electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 213 may further include a layer, including such as ITO, IZO, ZnO, or In₂O₃, on a (semi)transparent layer including the above-described material.

In some embodiments, a capping layer (not shown) may be further disposed on the opposite electrode 213. The capping layer may include an inorganic material such as lithium fluoride (LiF) and/or an organic material.

The thin-film encapsulation layer TFE may be disposed on the opposite electrode 213. In an embodiment, the thin-film encapsulation layer TFE may include at least one inorganic encapsulation layer and at least one organic encapsulation layer, and FIG. 7B shows an embodiment where the thin-film encapsulation layer TFE includes a first inorganic encapsulation layer 310, an organic encapsulation layer 320, and a second inorganic encapsulation layer 330 sequentially stacked on one another.

The first inorganic encapsulation layer 310 and the second inorganic encapsulation layer 330 may include at least one inorganic material selected from aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include acryl-based resin, epoxy-based resin, polyimide, or polyethylene. In an embodiment, the organic encapsulation layer 320 may include acrylate.

In an embodiment, at least one selected from the electrodes may include the graphene layer A-2. In an embodiment, for example, at least one selected from the source electrode S, the drain electrode D, the gate electrode G, the top electrode CE2, the bottom electrode CE1, the connection electrode CML, the pixel electrode 211, and the opposite electrode 213 may include the base portion A-1 and the graphene layer A-2. In such an embodiment, the graphene layer A-2 used in the electrode may not have extra treatment performed thereon and thus may have conductivity. In addition, the source electrode S, the drain electrode D, the gate electrode G, the top electrode CE2, the bottom electrode CE1, the connection electrode CML, and the pixel electrode 211 may be disposed on the substrate 100 in the form of a pattern. The opposite electrode 213 may be disposed on the entire surface of the substrate 100. In such an embodiment, the display substrate DS may be defined by layers from the substrate 100 to a layer disposed below each electrode. A method of forming the base portion A-1 and the graphene layer A-2 is the same as or similar to that described above, and thus, any repetitive detailed description thereof will be omitted.

Accordingly, the display device 1 may be used with low power, thereby increasing energy efficiency. In addition, the display device 1 may display an image with high luminance.

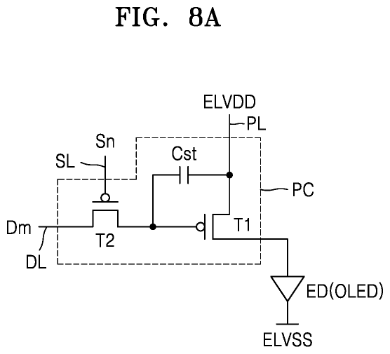

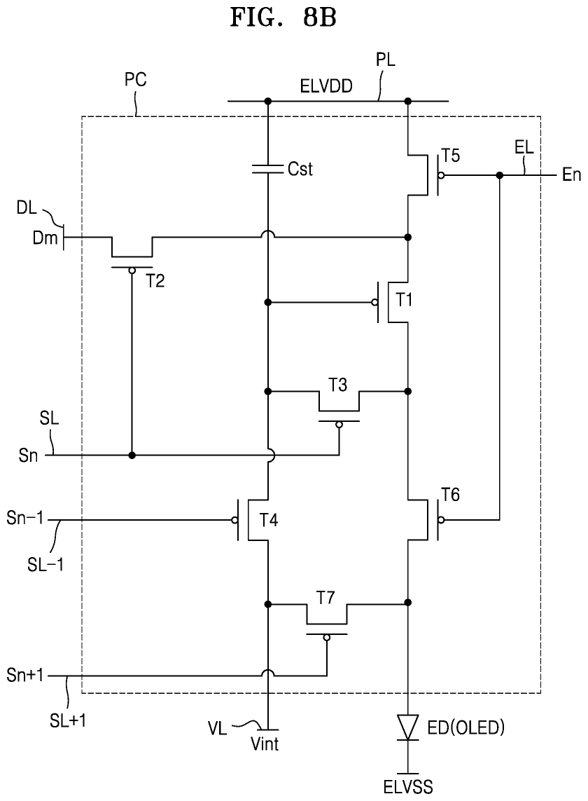

FIGS. 8A and 8B are schematic circuit diagrams of a circuit of the display device 1 shown in FIG. 6.

Referring to FIGS. 8A and 8B, in an embodiment, a pixel circuit PC may be connected to the display element ED to implement emission of sub-pixels. The pixel circuit PC may include a driving thin-film transistor T1, a switching thin-film transistor T2, and the storage capacitor Cst. The switching thin-film transistor T2 may be connected to a scan line SL and a data line DL and may be configured to transmit a data signal Dm input through the data line DL to the driving thin-film transistor T1 in response to a scan signal Sn input through the scan line SL.

The storage capacitor Cst may be connected to the switching thin-film transistor T2 and a driving voltage line PL and may store a voltage corresponding to a difference between a voltage received from the switching thin-film transistor T2 and a driving voltage ELVDD supplied to the driving voltage line PL.

The driving thin-film transistor T1 may be connected to the driving voltage line PL and the storage capacitor Cst and may be configured to control a driving current flowing through the display element ED from the driving voltage line PL, in response to a voltage value stored in the storage capacitor Cst. The display element ED may emit light having certain brightness corresponding to the driving current.

Although FIG. 8A shows an embodiment where the pixel circuit PC includes two thin-film transistors and one storage capacitor, one or more embodiments are not limited thereto.

Referring to FIG. 8B, in an alternative embodiment, the pixel circuit PC may include the driving thin-film transistor T1, the switching thin-film transistor T2, a compensation thin-film transistor T3, a first initialization thin-film transistor T4, an operation control thin-film transistor T5, an emission control thin-film transistor T6, and a second initialization thin-film transistor T7.

Although FIG. 8B shows an embodiment where signal lines, e.g., the scan line SL, a previous scan line SL−1, a next scan line SL+1, an emission control line EL, the data line DL, an initialization voltage line VL, and the driving voltage line PL are provided for each pixel circuit PC, one or more embodiments are not limited thereto. In another alternative embodiment, at least one selected from signal lines, e.g., the scan line SL, the previous scan line SL−1, the next scan line SL+1, the emission control line EL, the data line DL, and the initialization voltage line VL may be shared by neighboring pixel circuits.

A drain electrode of the driving thin-film transistor T1 may be electrically connected to the display element ED via the emission control thin-film transistor T6. The driving thin-film transistor T1 may be configured to receive the data signal Dm in response to a switching operation of the switching thin-film transistor T2 and supply a driving current to the display element ED.

A gate electrode of the switching thin-film transistor T2 may be connected to the scan line SL, and a source electrode of the switching thin-film transistor T2 may be connected to the data line DL. A drain electrode of the switching thin-film transistor T2 may be connected to a source electrode of the driving thin-film transistor T1 and may also be connected to the driving voltage line PL via the operation control thin-film transistor T5.

The switching thin-film transistor T2 may be turned on in response to the scan signal Sn received through the scan line SL and configured to perform a switching operation for transferring the data signal Dm transmitted through the data line DL to the source electrode of the driving thin-film transistor T1.

A gate electrode of the compensation thin-film transistor T3 may be connected to the scan line SL. A source electrode of the compensation thin-film transistor T3 may be connected to the drain electrode of the driving thin-film transistor T1 and may also be connected to a pixel electrode of the display element ED via the emission control thin-film transistor T6. A drain electrode of the compensation thin-film transistor T3 may be connected to one electrode of the storage capacitor Cst, a source electrode of the first initialization thin-film transistor T4, and a gate electrode of the driving thin-film transistor T1. The compensation thin-film transistor T3 may be turned on according to the scan signal Sn received through the scan line SL and configured to diode-connect the driving thin-film transistor T1 by connecting the gate electrode and the drain electrode of the driving thin-film transistor T1 to each other.

A gate electrode of the first initialization thin-film transistor T4 may be connected to the previous scan line SL−1. A drain electrode of the first initialization thin-film transistor T4 may be connected to the initialization voltage line VL. The source electrode of the first initialization thin-film transistor T4 may be connected to one electrode of the storage capacitor Cst, the drain electrode of the compensation thin-film transistor T3, and the gate electrode of the driving thin-film transistor T1. The first initialization thin-film transistor T4 may be turned on in response to a previous scan signal Sn−1 received through the previous scan line SL−1 and configured to perform an initialization operation for initializing a voltage of the gate electrode of the driving thin-film transistor T1 by transferring an initialization voltage Vint to the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 may be connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the display element ED. As the operation control thin-film transistor T5 and the emission control thin-film transistor T6 are simultaneously turned on according to an emission control signal En received through the emission control line EL, the driving voltage ELVDD may be transferred to the display element ED, and a driving current may flow through the display element ED.

A gate electrode of the second initialization thin-film transistor T7 may be connected to the next scan line SL+1. A source electrode of the second initialization thin-film transistor T7 may be connected to the pixel electrode of the display element ED. A drain electrode of the second initialization thin-film transistor T7 may be connected to the initialization voltage line VL. The second initialization thin-film transistor T7 may be turned on in response to a next scan signal Sn+1 received through the next scan line SL+1 and configured to initialize the pixel electrode of the display element ED.

Although FIG. 8B shows an embodiment where the first initialization thin-film transistor T4 and the second initialization thin-film transistor T7 are connected to the previous scan line SL−1 and the next scan line SL+1, respectively, one or more embodiments are not limited thereto. In another alternative embodiment, the first initialization thin-film transistor T4 and the second initialization thin-film transistor T7 may both be connected to the previous scan line SL−1 and thus may be driven according to the previous scan signal Sn−1.

The other electrode of the storage capacitor Cst may be connected to the driving voltage line PL. One electrode of the storage capacitor Cst may be connected to the gate electrode of the driving thin-film transistor T1, the drain electrode of the compensation thin-film transistor T3, and the source electrode of the first initialization thin-film transistor T4.

An opposite electrode (e.g., a cathode) of the display element ED may receive a common voltage ELVSS. The display element ED may receive a driving current from the driving thin-film transistor T1 and emit light.

The pixel circuit PC is not limited to the numbers of thin-film transistors and storage capacitors and the circuit design described with reference to FIGS. 8A and 8B, and the numbers of thin-film transistors and storage capacitors and the circuit design may be variously modified.

In a method and apparatus for manufacturing a display device, according to one or more of the embodiments described above, various layers including graphene may be directly provided or formed on a substrate. In a method and apparatus for manufacturing a display device, according to one or more of the embodiments described above, when a graphene layer is formed on a substate, the graphene layer does not have to be transferred onto the substrate, and thus, the graphene layer having a fine structure may be effectively formed.

In a method and apparatus for manufacturing a display device, according to one or more of the embodiments described above, a display device with increased efficiency may be manufactured.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display device, the apparatus comprising:
a stage on which a display substrate is arranged;
a nozzle portion facing the stage, wherein the nozzle portion supplies gas to the display substrate to form at least one selected from a base portion and a graphene layer on the display substrate; and
a driver connected to at least one selected from the nozzle portion and the stage, wherein the driver linearly moves the at least one selected from the nozzle portion and the stage in a predetermined direction,
wherein the nozzle portion forms the at least one selected from the base portion and the graphene layer on the display substrate based on a relative motion thereof with the stage.

2. The apparatus of claim 1, further comprising:
a heater which applies heat to the display substrate.

3. The apparatus of claim 1, further comprising:
a power supply portion electrically connected to the stage and the nozzle portion.

4. The apparatus of claim 1, further comprising:
a light source portion arranged at the nozzle portion or apart from the nozzle portion, wherein the light source portion linearly moves in a predetermined direction and emits light to the display substrate.

5. The apparatus of claim 1, wherein the nozzle portion comprises:
a first nozzle portion which supplies a first raw material to the display substrate;
a second nozzle portion which supplies a second raw material to the display substrate; and
a third nozzle portion arranged between the first nozzle portion and the second nozzle portion, wherein the third nozzle portion supplies a purge gas.

6. The apparatus of claim 5, wherein, based on a planar shape of the nozzle portion, the second nozzle portion is further from a center of the planar shape of the nozzle portion than the first nozzle portion is.

7. The apparatus of claim 6, wherein the nozzle portion further comprises a suction portion arranged between the first nozzle portion and the third nozzle portion and at an outer edge of the planar shape of the nozzle portion.

8. The apparatus of claim 7, wherein
the second nozzle portion is provided in plural, and
a plurality of second nozzle portions is arranged between the third nozzle portion and the suction portion.

9. The apparatus of claim 7, wherein the suction portion comprises:
a first suction portion arranged between the first nozzle portion and the third nozzle portion; and
a second suction portion arranged at the outer edge of the planar shape of the nozzle portion.

10. The apparatus of claim 9, wherein
the second suction portion is provided in plural, and
in a plan view, the first nozzle portion, a plurality of second nozzle portion, the third nozzle portion, and the first suction portion are arranged inside an arbitrary closed loop in which a plurality of second suction portions is arranged.

11. The apparatus of claim 1, further comprising:
a position sensor apart from the stage, wherein the position sensor senses a position of at least one selected from the display substrate and the nozzle portion.

12. The apparatus of claim 1, wherein the nozzle portion is provided with a hole having a diameter of about 0.5 μm or greater and about 100 μm or less.

13. The apparatus of claim 1, wherein the base portion comprises at least one selected from polyimide and transition metals.

14. A method of manufacturing a display device, the method comprising:
forming a base portion on a display substrate;
supplying a second graphene raw material onto the base portion while linearly moving at least one selected from the display substrate and a nozzle portion facing the display substrate; and
forming a graphene layer on the base portion by supplying a first graphene raw material onto the base portion, on which the second graphene raw material is supplied, while linearly moving the at least one selected from the display substrate and the nozzle portion facing the display substrate.

15. The method of claim 14, wherein at least one selected from the base portion and the graphene layer is formed in a pattern.

16. The method of claim 14, wherein the base portion comprises at least one selected from polyimide and transition metals.

17. The method of claim 14, wherein the forming the base portion on the display substrate comprises:
supplying a first base raw material onto the display substrate while linearly moving the at least one selected from the display substrate and the nozzle portion facing the display substrate; and
supplying a second base raw material onto the display substrate, on which the first base raw material is supplied, while linearly moving the at least one selected from the display substrate and the nozzle portion facing the display substrate.

18. The method of claim 17, wherein the forming the base portion on the display substrate further comprises supplying a purge gas onto the display substrate, on which the first base raw material is supplied, while linearly moving the at least one selected from the display substrate and the nozzle portion facing the display substrate.

19. The method of claim 14, further comprising:
supplying a purge gas onto the base portion on which the second graphene raw material is supplied while linearly moving the at least one selected from the display substrate and the nozzle portion facing the display substrate.

20. The method of claim 14, further comprising:
discharging at least one selected from the first graphene raw material and the second graphene raw material.

21. The method of claim 14, further comprising:
discharging the second graphene raw material to the outside along a circumference of a planar shape of the nozzle portion.
